(19) United States
(12) Patent Application Publication
(10) Pub. No.: US 2026/0239818 A1
(43) Pub. Date: Aug. 13, 2026

(54) LIGHT-EMITTING ELEMENT AND DISPLAY DEVICE

(71) Applicant: Sharp Display Technology Corporation, Kameyama City, Mie (JP)

(72) Inventor: SHINICHI HANDA, Sakai City, Osaka (JP)

(21) Appl. No.: 19/475,143

(22) PCT Filed: Apr. 18, 2023
(86) PCT No.: PCT/JP2023/015472

§ 371 Date: Oct. 14, 2025

(51) Int. Cl. H10K 50/15; H10K 50/115; H10K 59/00

(52) U.S. Cl. CPC H10K 50/15; H10K 50/115; H10K 59/771

(57) ABSTRACT

A light-emitting element includes: an anode; a cathode; a light-emitting layer provided between the anode and the cathode; and an electron transport layer, as a carrier transport layer, provided between the cathode and the light-emitting layer, wherein the light-emitting layer includes a plurality of quantum dots and a matrix provided at least partially between the plurality of quantum dots, the electron transport layer includes a layer of a mixture of at least a first material and a second material, and the first material differs from the second material.

### TECHNICAL FIELD

The present disclosure relates to light-emitting elements and display devices.

### BACKGROUND ART

Considerable attention has been given to QLEDs (quantum-dot light-emitting diodes), which are light-emitting elements containing quantum dots, and to display devices incorporating QLEDs for their potential to achieve, for example, low power consumption, small thickness, and high image quality.

For instance, Patent Literature 1 discloses quantum dots with fluoride-containing ligands or fluoride anions attached to the surfaces of the quantum dots.

### CITATION LIST

### Patent Literature

Patent Literature 1: Japanese Unexamined Patent Application Publication No. 2020-180278 (Publication Date: Nov. 5, 2020)

### SUMMARY

### Technical Problem

The disclosure described in Patent Literature 1 has a problem that the resultant light-emitting element exhibits low durability and low luminous efficiency.

The present disclosure, in an aspect thereof, has an object to provide a light-emitting element and a display device that allow for improvement in durability and luminous efficiency.

### Solution to Problem

To address these issues, a light-emitting element in accordance with the present disclosure includes:
an anode;
a cathode;
a light-emitting layer provided between the anode and the cathode; and
a carrier transport layer provided between either the anode or the cathode and the light-emitting layer, wherein
the light-emitting layer includes a plurality of quantum dots and a matrix provided at least partially between the plurality of quantum dots,
the carrier transport layer includes a layer of a mixture of at least a first material and a second material, and
the first material differs from the second material.

To address the issues, a display device in accordance with the present disclosure includes a plurality of these light-emitting elements, wherein
the plurality of light-emitting elements includes a first light-emitting element and a second light-emitting element that emits light of a different wavelength than does the first light-emitting element,
the first light-emitting element includes first quantum dots as the plurality of quantum dots,
the second light-emitting element includes second quantum dots as the plurality of quantum dots,
each of the first light-emitting element and the second light-emitting element includes, as the carrier transport layer, a common electron transport layer between the cathode and the light-emitting layer,
the common electron transport layer includes a layer of a mixture of at least the first material, the second material, and a third material that differs from the first material and the second material, and
the matrix, the first quantum dots, the second quantum dots, the first material, the second material, and the third material have electron affinities with magnitudes that have a relationship: Matrix≤Second Material<Second Quantum Dots≤Third Material<First Quantum Dots≤First Material.

To address the issues, another display device in accordance with the present disclosure includes a plurality of the light-emitting elements, wherein
the plurality of light-emitting elements includes a first light-emitting element and a second light-emitting element that emits light of a different wavelength than does the first light-emitting element,
the first light-emitting element includes first quantum dots as the plurality of quantum dots,
the second light-emitting element includes second quantum dots as the plurality of quantum dots,
each of the first light-emitting element and the second light-emitting element includes, as the carrier transport layer, a common hole transport layer between the anode and the light-emitting layer,
the common hole transport layer includes a layer of a mixture of at least the first material, the second material, and a third material that differs from the first material and the second material, and
the matrix, the first quantum dots, the second quantum dots, the first material, the second material, and the third material have ionization potentials with magnitudes that have a relationship: Matrix≥Second Material>Second Quantum Dots≥Third Material>First Quantum Dots≥First Material.

To address the issues, another display device in accordance with the present disclosure includes a plurality of the light-emitting elements, wherein
the plurality of light-emitting elements includes a first light-emitting element and a second light-emitting element that emits light of a different wavelength than does the first light-emitting element,
the first light-emitting element includes first quantum dots as the plurality of quantum dots and a first carrier transport layer as the carrier transport layer,
the second light-emitting element includes second quantum dots as the plurality of quantum dots and a second carrier transport layer as the carrier transport layer,
the first carrier transport layer includes a layer of a mixture of the first material and the second material, and
the second carrier transport layer includes a layer of a mixture of the first material, the second material, and a third material that differs from the first material and the second material.

### Advantageous Effects of Disclosure

The present disclosure, in an aspect thereof, can provide a light-emitting element and a display device that allow for improvement in durability and luminous efficiency.

### BRIEF DESCRIPTION OF DRAWINGS

FIG. 1 is a schematic cross-sectional view of a structure of a light-emitting element in accordance with Embodiment 1.

FIG. 2 is a diagram illustrating a region formed between two adjacent quantum dots that are among a plurality of quantum dots contained in a light-emitting layer of a light-emitting element in accordance with Embodiment 1 shown in FIG. 1 when the two adjacent quantum dots are positioned close to each other.

FIG. 3 is a diagram illustrating a region formed between two adjacent quantum dots that are among a plurality of quantum dots contained in a light-emitting layer of a light-emitting element in accordance with Embodiment 1 shown in FIG. 1 when the two adjacent quantum dots are positioned slightly apart from each other.

FIG. 4 is a schematic diagram of the band energy levels of a light-emitting layer of a light-emitting element in accordance with Embodiment 1 shown in FIG. 1.

FIG. 5 is a schematic diagram of the band energy levels of a hole transport layer, a light-emitting layer, and an electron transport layer of a light-emitting element in accordance with Embodiment 1 shown in FIG. 1.

FIG. 6 is a diagram representing a relationship between the particle radius, bandgap, and electron affinity of ZnO.

FIG. 7 is a diagram representing a relationship between the x value and the electron affinity of Zn₁₋ₓMgₓO.

FIG. 8 is an illustration of an electron injection mechanism in a light-emitting element in accordance with Embodiment 1 shown in FIG. 1.

FIG. 9 is a diagram schematically illustrating a structure of a light-emitting element in accordance with a variation example of Embodiment 1 and representing a preferable mix ratio of a first material and a second material in an electron transport layer.

FIG. 10 is a schematic cross-sectional view of a structure of a light-emitting element in accordance with Embodiment 2.

FIG. 11 is a schematic diagram of the band energy levels of a hole transport layer, a light-emitting layer, and an electron transport layer of a light-emitting element in accordance with Embodiment 2 shown in FIG. 10.

FIG. 12 is a diagram schematically illustrating a structure of a light-emitting element in accordance with a variation example of Embodiment 2 and representing a preferable mix ratio of a first material and a second material in a hole transport layer.

FIG. 13 is a schematic cross-sectional view of a structure of a display device in accordance with Embodiment 3.

FIG. 14 is an illustration of an electron injection mechanism in light-emitting elements in a display device in accordance with Embodiment 3 shown in FIG. 13.

FIG. 15 is a schematic cross-sectional view of a structure of a display device in accordance with Embodiment 4.

FIG. 16 is an illustration of an electron injection mechanism in light-emitting elements in a display device in accordance with Embodiment 4 shown in FIG. 15.

FIG. 17 is a schematic cross-sectional view of a structure of a display device in accordance with Embodiment 5.

FIG. 18 is an illustration of a hole injection mechanism in light-emitting elements in a display device in accordance with Embodiment 5 shown in FIG. 17.

FIG. 19 is a schematic cross-sectional view of a structure of a display device in accordance with Embodiment 6.

FIG. 20 is a schematic cross-sectional view of a structure of a display device in accordance with Embodiment 7.

### DESCRIPTION OF EMBODIMENTS

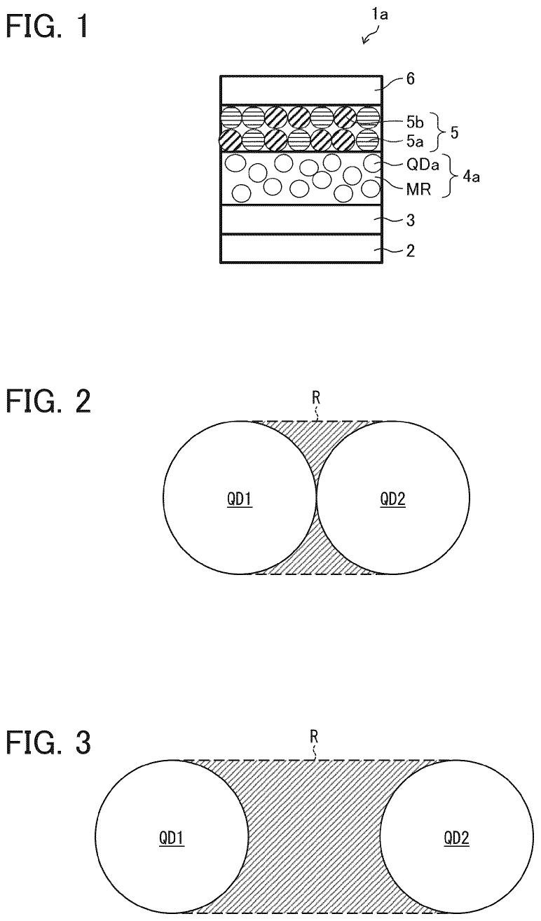

The following will describe embodiments of the present disclosure on the basis of FIGS. 1 to 20. Throughout the following description, members of an embodiment that have the same arrangement and function as members of a specific embodiment are denoted by the same reference numerals, and description thereof may be omitted for convenience of description.

### Embodiment 1

FIG. 1 is a schematic cross-sectional view of a structure of a light-emitting element 1a in accordance with Embodiment 1.

Referring to FIG. 1, the light-emitting element 1a includes: an anode 2; a cathode 6; a light-emitting layer 4a provided between the anode 2 and the cathode 6; an electron transport layer 5 that is a carrier transport layer provided between the cathode 6 and the light-emitting layer 4a; and a hole transport layer 3 that is a carrier transport layer provided between the anode 2 and the light-emitting layer 4a. The light-emitting layer 4a includes: a plurality of quantum dots QDa; and a matrix MR provided at least partially between the plurality of quantum dots QDa. The electron transport layer 5, which is a carrier transport layer, includes a layer of a mixture of at least a first material 5a and a second material 5b, and the first material 5a differs from the second material 5b. The present embodiment discusses an example where the electron transport layer 5 is composed of a layer of a mixture of the first material 5a and the second material 5b, which is merely illustrative. Alternatively, the electron transport layer 5 needs only to include a layer of a mixture of the first material 5a and the second material 5b. Note that the language, “the first material 5a differs from the second material 5b,” refers to one of the following three cases: the first material 5a and the second material 5b contain different component elements (case 1); the first material 5a and the second material 5b contain the same component elements with different composition ratios (case 2); and when both the first material 5a and the second material 5b are nanoparticles, the first material 5a and the second material 5b contain the same elements with the same composition ratio and have different particle diameter distributions (case 3).

The present embodiment discusses an example where the electron transport layer 5 resides as a carrier transport layer between the cathode 6 and the light-emitting layer 4a, and the hole transport layer 3 resides as a carrier transport layer between the anode 2 and the light-emitting layer 4a, which is merely illustrative. Alternatively, the carrier transport layer may be provided at least either between the cathode 6 and the light-emitting layer 4a or between the anode 2 and the light-emitting layer 4a, either one or both of an electron transport layer and an electron injection layer may be provided as a carrier transport layer between the cathode 6 and the light-emitting layer 4a, and either one or both of a hole transport layer and a hole injection layer may be provided as a carrier transport layer between the anode 2 and the light-emitting layer 4a.

In the light-emitting element 1a, the anode 2 contains a conductive material and is in contact with the hole transport layer 3, and the cathode 6 contains a conductive material and is in contact with the electron transport layer 5.

Either one or both of the anode 2 and the cathode 6 include(s) a transparent conductive film. The transparent conductive film contains, for example: ITO (indium tin oxide), IZO (indium zinc oxide), ZnO, AZO (aluminum-doped zinc oxide), or BZO (boron-doped zinc oxide); or a thin layer, nanoparticles, or a nanowire of Ag, Al, Cu, or Au. The transparent conductive film can be formed by, for example, sputtering, vapor deposition, or coating.

Either one of the anode 2 and the cathode 6 may be made of a metal. This metal is preferably Al, Cu, Au, or Ag, which exhibit high reflectance to visible light.

The hole transport layer 3 is made of, for example, a p-type oxide semiconductor (e.g., NiO, MgNiO, or Cu₂O) or an organic material such as PEDOT (polyethylenedioxythiophene): PSS (polystyrene sulfonate)/PVK (poly-N-vinyl carbazole). The hole transport layer 3 can be formed by, for example, coating, sputtering, or vapor deposition.

The light-emitting layer 4a includes the quantum dots QDa and the matrix MR. The quantum dots QDa are, for example, quantum dots that has a core/shell structure such as CdSe/CdS, CdSe/ZnS, InP/ZnS, ZnSe/ZnS, or CIGS/ZnS. In addition, the quantum dots QDa may contain, for example, organic ligands or inorganic ligands (e.g., halogen ligands).

Here, “quantum dots” refers to dots that have a maximum width of less than or equal to 100 nm. The shape of the quantum dots is not limited in any particular manner so long as the quantum dots satisfy this maximum width and is not necessarily limited to a spherical three-dimensional shape (circular cross-sectional shape). The quantum dots may have, for example, a polygonal cross-sectional shape, a virgulate three-dimensional shape, a ramal three-dimensional shape, a three-dimensional shape with an irregular surface, or a combination of any of these shapes.

The present embodiment discusses an example where the matrix MR is loaded into the spaces between the plurality of quantum dots QDa in the light-emitting layer 4a of the light-emitting element 1a as shown in FIG. 1, which is merely illustrative. Alternatively, the matrix MR may be provided at least partially between the plurality of quantum dots QDa in the light-emitting layer 4a.

The present embodiment discusses an example where the matrix MR is formed of, for example, a metal sulfide (e.g., ZnS (ionization potential: 7.2 eV, electron affinity: 3.2 eV)) that is also a material for the above-described shells of the quantum dots QDa, which is merely illustrative.

When the matrix MR contains a metal sulfide, the matrix MR can be formed by applying a solution containing a precursor to the metal sulfide and baking the solution as will be detailed later. In addition, the light-emitting layer containing the matrix MR containing a metal sulfide is relatively stable to, for example, oxygen and water and is highly reliable.

FIG. 2 is a diagram illustrating a region R formed between two adjacent quantum dots QD1 and QD2 that are among the plurality of quantum dots QDa contained in the light-emitting layer 4a of the light-emitting element 1a shown in FIG. 1 when the two adjacent quantum dots QD1 and QD2 are positioned close to each other.

FIG. 3 is a diagram illustrating a region R formed between the quantum dot QD1 and the quantum dot QD2, which are among the plurality of quantum dots QDa contained in the light-emitting layer 4a of the light-emitting element 1a shown in FIG. 1, when the two adjacent quantum dots QD1 and QD2 are positioned slightly apart from each other.

The region R shown in FIGS. 2 and 3 is surround by two straight lines (external common tangents) that are in contact with the outer circumferences of the two adjacent quantum dots QD1 and QD2 and by the opposing outer circumferences of the two adjacent quantum dots QD1 and QD2. The region R is present and loaded with the matrix MR both when the two adjacent quantum dots QD1 and QD2 are positioned close to each other as shown in FIG. 2 and when the two adjacent quantum dots QD1 and QD2 are positioned slightly apart from each other as shown in FIG. 3. The language, “the matrix MR is loaded between the two adjacent quantum dots QD1 and QD2,” means that the region R shown in FIGS. 2 and 3 is either loaded or filled with the matrix MR. Note that in the present disclosure, the two adjacent quantum dots QD1 and QD2 may be held in place by the presence of the matrix MR in the region R, for example, at least a part of the region R may be loaded with the matrix MR.

The present embodiment discusses an example where the region R formed between the two adjacent quantum dots QD1 and QD2 shown in FIGS. 2 and 3, in other words, the empty space between the plurality of quantum dots QDa, is loaded with the matrix MR, which is merely illustrative.

Note that the language, “the quantum dots QD1 and QD2 are held in place by the matrix MR that is present in the region R formed between the two adjacent quantum dots QD1 and QD2,” means that at least a part of the region R is filled in with the matrix MR and is unarguably inclusive of the entire region R being filled up with the matrix MR and also inclusive of a part of the region R being filled up with the matrix MR.

The matrix MR may be formed so as to fill in the regions (spaces) other than the plurality of quantum dots QDa in the light-emitting layer 4a. In addition, referring to FIG. 1, the matrix MR may provide a periphery of the light-emitting layer 4a, and the plurality of quantum dots QDa may be positioned away from this periphery. In other words, the matrix MR may encage the plurality of quantum dots QDa. Furthermore, at least a part of the periphery of the light-emitting layer 4a may be provided by the matrix MR and the quantum dots QDa. In addition, the plurality of quantum dots QDa may be embedded at intervals in the matrix MR. Note that the “periphery” in this context refers to a first surface of the light-emitting layer 4a (e.g., a face of the light-emitting layer 4a that is in contact with the electron transport layer 5 shown in FIG. 1) and a second surface of the light-emitting layer (e.g., a face of the light-emitting layer 4a that is in contact with the hole transport layer 3 shown in FIG. 1).

The matrix MR may include a continuous film. A continuous film is a film that is not broken up by a material other than the material for the continuous film. The continuous film may be something like an integral film that is contiguous without being divided up by chemical bonds of a compound contained in the matrix MR. The continuous film may be formed, for example, as a film that has an area of at least 1,000 nm² when measured in the in-plane direction that is perpendicular to the film thickness direction.

The language, “the matrix is provided at least partially between the plurality of quantum dots,” will suffice if it is confirmed that the matrix MR is at least loaded between the two quantum dots QDa or in contact with the quantum dots QDa. In addition, the structure of the matrix MR can be identified by analyzing the material of the matrix MR positioned in the middle of the two quantum dots QDa, and when the middle of the two quantum dots QDa is a cavity, the structure of the matrix MR can be identified by analyzing the material of the inner wall of this cavity.

The light-emitting layer 4a shown in FIG. 1, containing the quantum dots QDa and the matrix MR, can be formed by, for example, applying a quantum dot solution containing the plurality of quantum dots QDa, a precursor to a metal sulfide that is a precursor to the matrix MR, and a solvent. The precursor to the metal sulfide may be, for example, zinc ethylxanthate which provides ZnS, and the solvent may be, for example, N,N-dimethyl formamide or dimethyl sulfoxide.

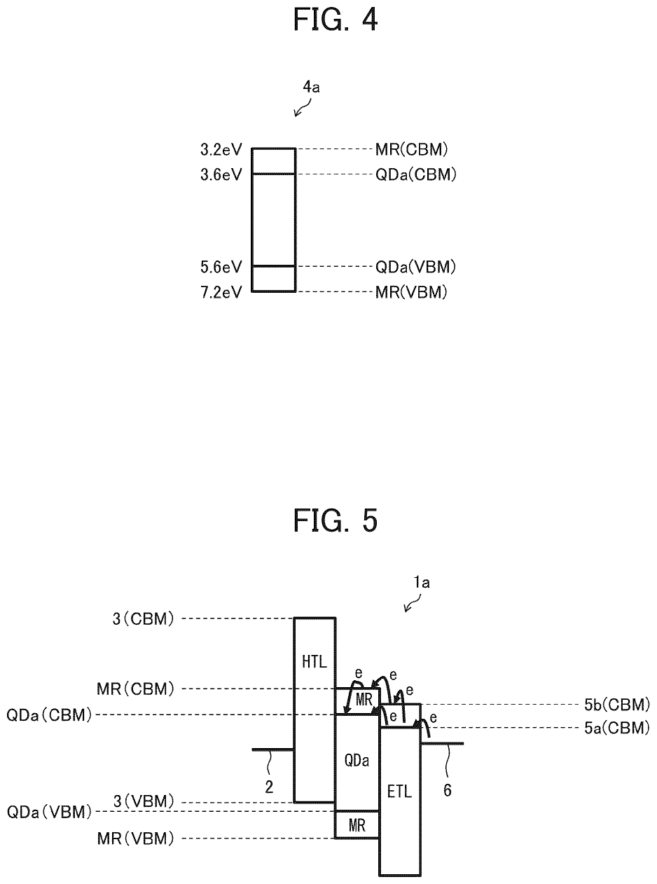

FIG. 4 is a schematic diagram of the band energy levels of the light-emitting layer 4a of the light-emitting element 1a in accordance with Embodiment 1 shown in FIG. 1. The light-emitting element 1a, including the light-emitting layer 4a, is, for example, a red-light-emitting element including a red-light-emitting layer.

In the present embodiment, since CdSe (Red) is used as the core portions of the quantum dots QDa, and ZnS is used as the matrix MR, the energy level of the conduction band minimum (QDa(CBM)) of the core portions of the quantum dots QDa is 3.6 eV, the energy level of the valence band maximum (QDa(VBM)) of the core portions of the quantum dots QDa is 5.6 eV, the energy level of the conduction band minimum (MR(CBM)) of the matrix MR is 3.2 eV, and the energy level of the valence band maximum (MR(VBM)) of the matrix MR is 7.2 eV, as shown in FIG. 4. Note that since the shell portions of the quantum dots QDa and the matrix MR are made of ZnS in the present embodiment as described above, FIG. 4 does not show the energy level of the conduction band minimum of the shell portions of the quantum dots QDa, which is equal to the energy level of the conduction band minimum (MR(CBM)) of the matrix MR, and the energy level of the valence band maximum of the shell portions of the quantum dots QDa, which is equal to the energy level of the valence band maximum (MR(VBM)) of the matrix MR.

Note that the absolute value of the difference between the vacuum energy level and the energy level of the valence band maximum (VBM) is equal to the value of the ionization potential and that the absolute value of the difference between the vacuum energy level and the energy level of the conduction band minimum (CBM) is equal to the value of the electron affinity.

FIG. 5 is a schematic diagram of the band energy levels of the hole transport layer 3, the light-emitting layer 4a, and the electron transport layer 5 of the light-emitting element 1a in accordance with Embodiment 1 shown in FIG. 1.

Referring to FIG. 5, since the electron transport layer 5, which is a carrier transport layer, includes a layer of a mixture of at least the first material 5a and the second material 5b, and the first material 5a differs from the second material 5b, the electron affinity of the first material 5a (the absolute value of the difference between the vacuum energy level and the energy level of the conduction band minimum (5a(CBM)) of the first material 5a) differs from the electron affinity of the second material 5b (the absolute value of the difference between the vacuum energy level and the energy level of the conduction band minimum (5b(CBM)) of the second material 5b).

As described in the foregoing, the use of the electron transport layer 5 including a layer of a mixture of the first material 5a and the second material 5b, which are different materials, enables appropriately adjusting the energy levels through the injection of electrons e from the cathode 6 to a light-emitting layer 4a including the matrix MR in comparison with when an electron transport layer composed of a single material is used, thereby enabling readily injecting electrons e from the cathode 6 to the electron transport layer 5 and also from the electron transport layer 5 to the light-emitting layer 4a including the matrix MR, which in turn enables voltage reduction.

In other words, the use of the electron transport layer 5 including a layer of a mixture of the first material 5a and the second material 5b, which are different materials, enables rendering the electron affinity of the first material 5a and the electron affinity of the second material 5b differ from each other, thereby enabling easily injecting electrons e to the light-emitting layer 4a in which the quantum dots QDa and the matrix MR have different energy levels.

In addition, the use of the electron transport layer 5 including a layer of a mixture of the first material 5a and the second material 5b, which are different materials, enables a plurality of energy levels (electron affinities) at which electrons e are injected from the electron transport layer 5 to the light-emitting layer 4a. It also becomes possible to readily move electrons e in the electron transport layer 5 from the first material 5a, which exhibits a deep energy level, to the second material 5b, which exhibits a shallow energy level. Consequently, it becomes possible to efficiently inject electrons e from the first material 5a and the second material 5b to the quantum dots QDa and the matrix MR, which have different energy levels.

Note that FIG. 5 depicts the energy level of the conduction band minimum (QDa(CBM)) of the core portions of the quantum dots QDa as being shallower than the energy level of the conduction band minimum (5a(CBM)) of the first material 5a. However, effects that are similar to the effects described above can be achieved when the energy level of the conduction band minimum (QDa(CBM)) of the core portions of the quantum dots QDa is deeper than the energy level of the conduction band minimum (5a(CBM)) of the first material 5a.

The light-emitting layer 4a has a surface formed of two different materials, that is, the quantum dots QDa and the matrix MR. The electron transport layer 5 likewise including two different materials, that is, a layer of a mixture of the first material 5a and the second material 5b, improves adherence between the light-emitting layer 4a and the electron transport layer 5, thereby enabling improving, for example, conductance and mechanical stress resistance at the interface. In addition, it becomes easier to planarize both the light-emitting layer 4a and the electron transport layer 5, thereby enabling improving the in-plane uniformity of light emission.

Referring to FIG. 5, the electron affinity of the second material 5b (the absolute value of the difference between the vacuum energy level and the energy level of the conduction band minimum (5b(CBM)) of the second material 5b) is preferably smaller than the electron affinity of the first material 5a (the absolute value of the difference between the vacuum energy level and the energy level of the conduction band minimum (5a(CBM)) of the first material 5a), and the electron affinity of the core portions of the quantum dots QDa (the absolute value of the difference between the vacuum energy level and the energy level of the conduction band minimum (QDa(CBM)) of the core portions of the quantum dots QDa) is preferably smaller than or equal to the electron affinity of the first material 5a.

In this configuration, since the electron affinity decreases in the order of the cathode 6, the first material 5a, and the core portions of the quantum dots QDa, it becomes possible to inject electrons e to the core portions of the quantum dots QDa at a low voltage, which reduces the drive voltage of the light-emitting element 1a.

The electron affinity of the matrix MR (the absolute value of the difference between the vacuum energy level and the energy level of the conduction band minimum (MR(CBM)) of the matrix MR) is preferably smaller than or equal to the electron affinity of the second material 5b.

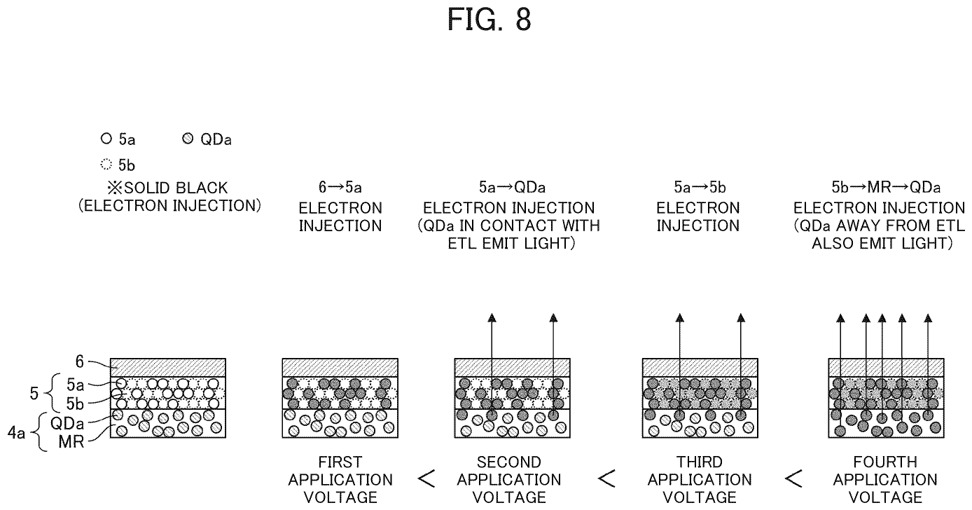

In this configuration, since the electron affinity decreases in the order of the cathode 6, the first material 5a, the second material 5b, and the matrix MR, it becomes possible to inject electrons e also to the matrix MR at a low voltage. To describe it briefly (details will be given later on the basis of FIG. 8), the electrons e injected to the matrix MR can move to the quantum dots QDa, which are positioned away from the electron transport layer 5, and recombine in the quantum dots QDa to emit light. Therefore, it is possible to cause those quantum dots QDa which are located away from the electron transport layer 5 to emit light at a relatively low voltage, which enables achieving a high luminance. A higher voltage allows those quantum dots QDa which are located farther away from the electron transport layer 5 to emit light, thereby enabling reducing roll off. In other words, the current dependency and voltage dependency of the luminous efficiency can be improved, and decreases in the luminous efficiency can be reduced, in particular, in a large current region.

The electron affinity of the second material 5b is preferably smaller than the electron affinity of the core portions of the quantum dots QDa.

In this configuration, electrons e are readily injected from the first material 5a to the core portions of the quantum dots QDa and also from the second material 5b to the matrix MR, both at a low voltage.

Meanwhile, if the electron affinity of the second material 5b is higher than the electron affinity of the core portions of the quantum dots QDa, electrons e are injected from the second material 5b both to the matrix MR and to the core portions of the quantum dots QDa.

The electron affinity of the first material 5a and the electron affinity of the second material 5b preferably differ by at least 0.1 eV.

The difference in the ease of injecting electric current changes by approximately 50 times for every 0.1 eV difference in electron affinity, and electric current can be therefore passed to a material with a more suitable electron affinity in preference to other materials.

Each of the first material 5a and the second material 5b is preferably composed of an inorganic compound.

In this configuration, the light-emitting element 1a can exhibit increased reliability.

The first material 5a and the second material 5b are preferably nanoparticles and have volume ratios to the electron transport layer 5 that increase with a decrease in their electron affinities. In the present embodiment, the volume ratio of the second material 5b contained in the electron transport layer 5 is preferably larger than the volume ratio of the first material 5a contained in the electron transport layer 5. This configuration facilitates the injection of electrons e to nanoparticles with a low electron affinity, thereby enabling improving the injection of electrons e to the matrix MR, which has a low injection efficiency.

The first material 5a and the second material 5b are preferably nanoparticles and have volume ratios to the electron transport layer 5 that increase with an increase in their electron affinities in the vicinity of their interface with the cathode 6. In the present embodiment, the volume ratio of the first material 5a contained in the electron transport layer 5 is preferably larger than the volume ratio of the second material 5b contained in the electron transport layer 5. This configuration facilitates the injection of electrons e from the cathode 6 to the electron transport layer 5. Note that the “vicinity of an interface” refers to the region within a 30-nm range from the interface.

The first material 5a and the second material 5b are preferably nanoparticles and have volume ratios to the electron transport layer 5 that increase with a decrease in their electron affinities in the vicinity of their interface with the light-emitting layer 4a. In the present embodiment, the volume ratio of the second material 5b contained in the electron transport layer 5 is preferably larger than the volume ratio of the first material 5a contained in the electron transport layer 5. This configuration facilitates the injection of electrons e from the electron transport layer 5 to the matrix MR.

The first material 5a and the second material 5b are preferably nanoparticles, and the first material 5a preferably decreases from the cathode 6 side toward the light-emitting layer 4a side. This configuration presents no obstacle in injecting electrons e first to the first material 5a and then to the second material 5b in accordance with the direction in which electrons e are flowing, thereby reducing voltage inside the electron transport layer 5 to a minimum. The second material 5b preferably increases from the cathode 6 side toward the light-emitting layer 4a side. This configuration presents no obstacle in injecting electrons e first to the first material 5a and then to the second material 5b in accordance with the direction in which electrons e are flowing, thereby reducing voltage inside the electron transport layer 5 to a minimum.

In the present embodiment, since CdSe (Red) is used as the core portions of the quantum dots QDa, and ZnS is used as the matrix MR, the energy level of the conduction band minimum (QDa(CBM)) of the core portions of the quantum dots QDa and the electron affinity of the core portions of the quantum dots QDa are 3.6 eV, and the energy level of the conduction band minimum (MR(CBM)) of the matrix MR and the electron affinity of the matrix MR are 3.2 eV. Therefore, the electron affinity of the first material 5a is preferably at least 3.6 eV, and the electron affinity of the second material 5b is preferably from 3.2 eV, inclusive, to 3.6 eV, exclusive.

For instance, the first material 5a may be suitably at least one compound selected from TiO₂ and SnO₂, and the second material 5b may be suitably at least one compound selected from GaP, AlSb, ZrO₂, GaN, ZnS, and ZnTe.

It is assumed in this context that the electron affinity and ionization potential of each material have the values shown below in Table 1.

TABLE 1

| | Ionization | Electron |
|---|---|---|
| Material | Potential (eV) | Affinity (eV) |
| TiO₂ | 7.4 | 4.2 |
| SnO₂ | 7.7 | 4.2 |
| GaP | 6.1 | 3.5 |
| AlSb | 5.3 | 3.4 |
| ZrO₂ | 9.0 | 3.4 |
| GaN | 7.2 | 3.2 |
| ZnS | 7.2 | 3.2 |
| ZnTe | 5.8 | 3.2 |
| Ca₂SnO₄ | 8.1 | 3.0 |
| CaSnO₃ | 8.0 | 3.2 |
| Cu₂O | 5.5 | 3.3 |
| NiO | 5.4 | 2.0 |
| LaNiO₃ | 6.0 | 3.7 |
| CdSe(Red) | 5.6 | 3.6 |
| CdSe(Green) | 5.6 | 3.3 |
| CdSe(Blue) | 5.6 | 2.9 |
| CdTe(Red) | 5.2 | 3.2 |
| InN(Red) | 6.5 | 4.5 |
| InP(Red) | 5.4 | 3.4 |
| InP(Green) | 5.4 | 3.1 |
| ZnSe(Blue) | 5.8 | 3.1 |

The color of the light emitted by quantum dots is shown in parentheses.

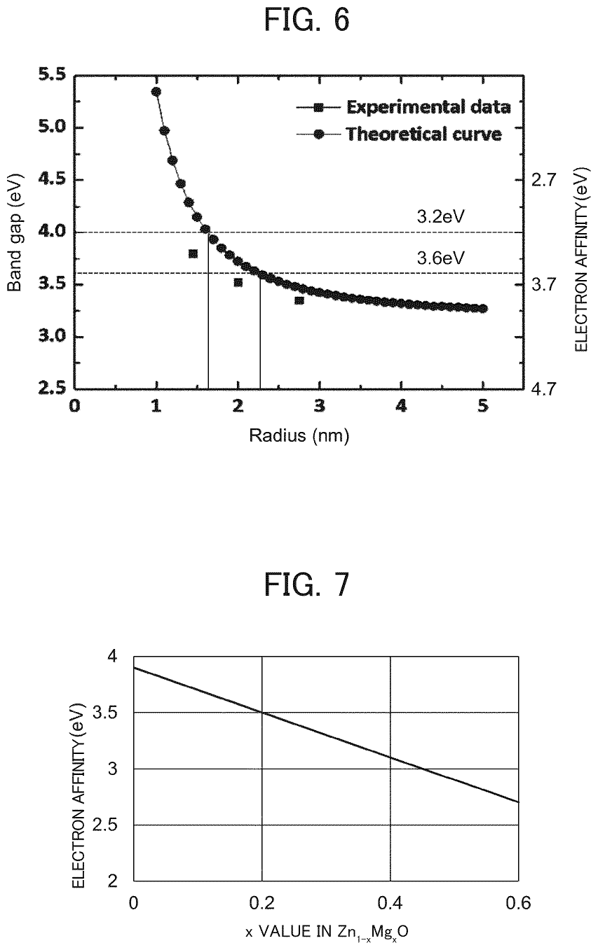

FIG. 6 is a diagram representing a relationship between the particle radius, bandgap, and electron affinity of ZnO.

The first material 5a and the second material 5b contained in the electron transport layer 5 are preferably nanoparticles and are preferably, for example, ZnO nanoparticles.

In ZnO nanoparticles, the bandgap increases, and the electron affinity decreases, with a decrease in the particle diameter due to quantum effects. Therefore, the electron transport layer 5 with two electron affinities can be provided by changing the particle diameters of the first material 5a and the second material 5b.

In the present embodiment, since CdSe (Red) is used as the core portions of the quantum dots QDa, and ZnS is used as the matrix MR, the electron affinity of the first material 5a is preferably at least 3.6 eV, and the electron affinity of the second material 5b is preferably from 3.2 eV, inclusive, to 3.6 eV, exclusive.

Thus, when ZnO nanoparticles are used as the first material 5a and the second material 5b, the first material 5a may be ZnO nanoparticles with an average particle diameter of at least 4.5 nm and a radius of at least 2.25 nm, and the second material 5b may be ZnO nanoparticles with an average particle diameter of from 3.2 nm, inclusive, to 4.5 nm, exclusive, and a radius of from 1.6 nm, inclusive, to 2.25 nm, exclusive, as shown in FIG. 6.

The first material 5a and the second material 5b may contain the same elements with the same composition ratio and have different particle diameter distributions.

The electron transport layer 5 contains: the first material 5a that has a first particle diameter distribution; and the second material 5b that has a second particle diameter distribution that differs from the first particle diameter distribution. For example, the electron transport layer 5 contains: the first material 5a that has a particle diameter distribution that spreads within approximately 15% below and above the particle diameter of 12 nm; and the second material 5b that has a particle diameter distribution that spreads within approximately 15% below and above the particle diameter of 4 nm.

The “particle diameter” in this context refers to the diameter of the circle that has an area corresponding to the area of the particles observed in an observation of the cross-section of the layer containing the particles. The language, “different particle diameter distributions,” does not necessarily mean that the two particle diameter distributions are completely separate, and the different particle diameter distributions may partially overlap. The electron transport layer 5 containing the first material 5a and the second material 5b is described as containing particles with two different particle diameter distributions if at least two particle diameter peaks are found in an observation of the cross-section of the electron transport layer 5.

FIG. 7 is a diagram representing a relationship between the x value and the electron affinity of Zn₁₋ₓMgₓO.

The first material 5a and the second material 5b contained in the electron transport layer 5 may contain the same component elements with different composition ratios.

For instance, the first material 5a and the second material 5b may be nanoparticles of Zn₁₋ₓMgₓO with an average particle diameter of 12 nm. Referring to FIG. 7, the electron affinity changes when the x value in Zn₁₋ₓMgₓO changes. Therefore, the electron transport layer 5 comes to exhibit two electron affinities when the first material 5a and the second material 5b have different x values.

As described above, the electron affinity of the first material 5a is preferably at least 3.6 eV, and the electron affinity of the second material 5b is preferably from 3.2 eV, inclusive, to 3.6 eV, exclusive.

Therefore, the first material 5a preferably has an x value of from 0 to 0.15, both inclusive, and the second material 5b preferably has an x value of from 0.15, exclusive, to 0.35, inclusive.

FIG. 8 is an illustration of an injection mechanism for electrons e in the light-emitting element 1a in accordance with Embodiment 1 shown in FIG. 1. Note that in FIG. 8, a second application voltage is higher than a first application voltage, a third application voltage is higher than the second application voltage, and a fourth application voltage is higher than the third application voltage.

Referring to FIG. 8, at the first application voltage and the second application voltage, electrons e can be injected, via the first material 5a, from the cathode 6 to those quantum dots QDa which are in contact with the electron transport layer 5 at a relatively low voltage, so that the electrons e can recombine with holes h to emit light.

Referring to FIG. 8, at the third application voltage and the fourth application voltage, electrons e can be injected from the cathode 6 to the matrix MR via the first material 5a and the second material 5b at a relatively low voltage. Then, the electrons e injected to the matrix MR are injected to the quantum dots QDa inside the light-emitting layer 4a and recombine with holes h to emit light.

There is a particular need to inject electrons e via the matrix MR to those quantum dots QDa which are not in contact with the electron transport layer 5. Active injection of electrons e to the matrix MR at a low voltage allows those quantum dots QDa which are at a distance from the electron transport layer 5 to emit light at a relatively low voltage, which enables achieving a high luminance.

Therefore, the light-emitting element 1a can be driven at a low voltage without causing a decrease in luminous efficiency. In addition, a higher voltage allows those quantum dots QDa which are located farther away from the electron transport layer 5 to emit light, thereby enabling reducing roll off. In other words, the current dependency and voltage dependency of the luminous efficiency can be improved, and decreases in the luminous efficiency can be reduced, in particular, in a large current region. The light-emitting element 1a, owing to the inclusion of the matrix MR, exhibits improved durability and, for the above-described reasons, also exhibits improved luminous efficiency. Thus, the display device including the light-emitting element 1a also exhibits improved durability and luminous efficiency.

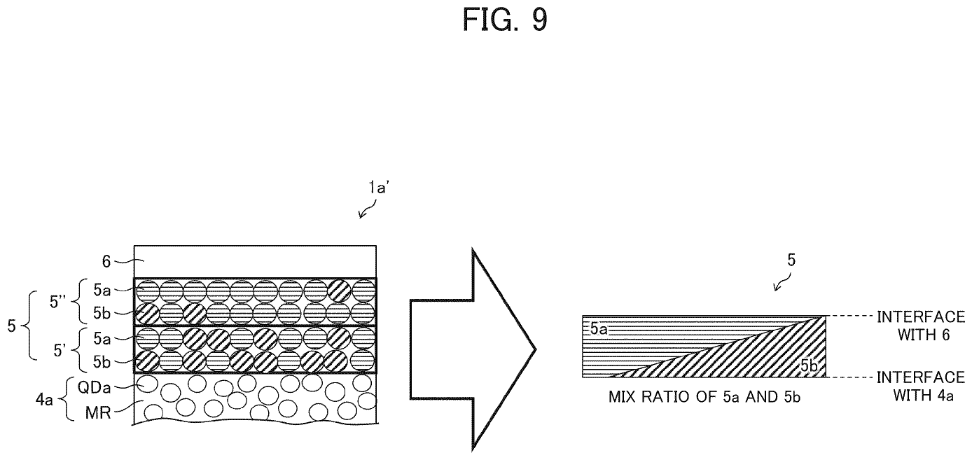

FIG. 9 is a diagram schematically illustrating a structure of a light-emitting element 1a′ in accordance with a variation example of Embodiment 1 and representing a preferable mix ratio of the first material 5a and the second material 5b in the electron transport layer 5.

Referring to FIG. 9, the electron transport layer 5 included in the light-emitting element 1a′ preferably includes a first electron transport layer 5′ and a second electron transport layer 5″, the first electron transport layer 5′ is preferably disposed closer to the light-emitting layer 4a than is the second electron transport layer 5″, the first electron transport layer 5′ preferably contains a mixture of at least the first material 5a and the second material 5b, and the quantity of the first material 5a contained in a unit volume of the second electron transport layer 5″ is preferably greater than the quantity of the first material 5a contained in a unit volume of the first electron transport layer 5′.

At the interface between the cathode 6 and the electron transport layer 5 of the light-emitting element 1a′, the first material 5a is preferably present in greater quantity than the second material 5b and more preferably exclusively present with no second material 5b at all. Therefore, for example, the first electron transport layer 5′ may contain a mixture of at least the first material 5a and the second material 5b, and the second electron transport layer 5″ may be composed solely of the first material 5a. This configuration presents no obstacle in injecting electrons e first to the second electron transport layer 5″ and then to the first electron transport layer 5′ in accordance with the direction in which electrons e are flowing, thereby reducing voltage inside the electron transport layer 5 to a minimum.

Meanwhile, at the interface between the light-emitting layer 4a and the electron transport layer 5 of the light-emitting element 1a′, the second material 5b is preferably present in greater quantity than the first material 5a. This configuration positions the second material 5b, from which it is easy to inject electrons e to the matrix MR, in great quantity close to the matrix MR, to which it is difficult to inject electrons e, thereby enabling improving luminous efficiency.

In addition, as described above, when the electron transport layer 5 includes a layer of a mixture of the first material 5a and the second material 5b, the electron transport layer 5 may be configured such that the second material 5b gradually increases, and the first material 5a gradually decreases, upon moving from the cathode 6 toward the light-emitting layer 4a. This configuration presents no obstacle in injecting electrons e first to the first material 5a and then to the second material 5b in accordance with the direction in which electrons e are flowing, thereby reducing voltage inside the electron transport layer 5 to a minimum.

The electron transport layer 5 shown in FIG. 9 may be formed by, for example, applying a solution of nanoparticles for the second material 5b by spin-coating and then applying, before drying, a solution of nanoparticles for the first material 5a by spin-coating and may alternatively be formed by, for example, preparing a plurality of solutions of nanoparticles for the first material 5a and nanoparticles for the second material 5b with different mix ratios (mix concentrations) and applying the solutions, one at a time, in ascending order of the mix ratio (mix concentration) of the first material 5a in the solution as if forming a stack of layers so that the resultant electron transport layer 5 can exhibit a concentration distribution in the film thickness direction.

Note that the present embodiment has so far discussed an example where the light-emitting layer 4a is formed before the electron transport layer 5 shown in FIG. 9 is formed, which is merely illustrative. Alternatively, for example, when the cathode 6, the electron transport layer 5 shown in FIG. 9, and the light-emitting layer 4a are formed in this order, the electron transport layer 5 may be formed by applying a solution of nanoparticles for the first material 5a by spin-coating and then applying, before drying, a solution of nanoparticles for the second material 5b by spin-coating and may alternatively be formed by preparing a plurality of solutions of nanoparticles for the first material 5a and nanoparticles for the second material 5b with different mix ratios (mix concentrations) and applying the solutions, one at a time, in descending order of the mix ratio (mix concentration) of the first material 5a in the solution as if forming a stack of layers so that the resultant electron transport layer 5 can exhibit a concentration distribution in the film thickness direction.

### Embodiment 2

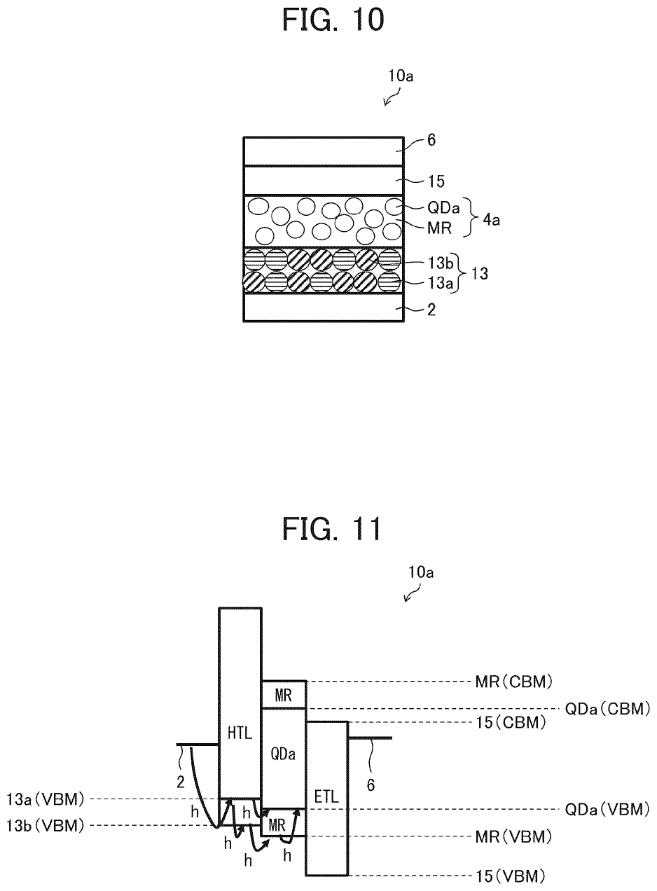

FIG. 10 is a schematic cross-sectional view of a structure of a light-emitting element 10a in accordance with Embodiment 2. Members of the present embodiment that are similar to those described earlier in Embodiment 1 are denoted by similar reference numerals, and detailed description thereof is not repeated.

The light-emitting element 10a shown in FIG. 10 includes: an anode 2; a cathode 6; a light-emitting layer 4a provided between the anode 2 and the cathode 6; an electron transport layer 15 that is a carrier transport layer provided between the cathode 6 and the light-emitting layer 4a; and a hole transport layer 13 that is a carrier transport layer provided between the anode 2 and the light-emitting layer 4a. The hole transport layer 13, which is a carrier transport layer, includes a layer of a mixture of at least a first material 13a and a second material 13b, and the first material 13a differs from the second material 13b. The present embodiment discusses an example where the hole transport layer 13 is composed of a layer of a mixture of the first material 13a and the second material 13b, which is merely illustrative. Alternatively, the hole transport layer 13 needs only to include a layer of a mixture of the first material 13a and the second material 13b. Note that the language, “the first material 13a differs from the second material 13b,” refers to one of the following three cases: the first material 13a and the second material 13b contain different component elements (case 1); the first material 13a and the second material 13b contain the same component elements with different composition ratios (case 2); and when both the first material 13a and the second material 13b are nanoparticles, the first material 13a and the second material 13b contain the same elements with the same composition ratio and have different particle diameter distributions (case 3).

The electron transport layer 15 is formed of, for example, an n-type oxide semiconductor (e.g., ZnO, Zn₁₋ₓMgₓO (0≤x<1), TiO₂, or SnO₂). The electron transport layer 15 may be either nanoparticles or a continuous film. The electron transport layer 15 may be formed by, for example, coating, sputtering, or vapor deposition.

FIG. 11 is a schematic diagram of the band energy levels of the hole transport layer 13, the light-emitting layer 4a, and the electron transport layer 15 of the light-emitting element 10a in accordance with Embodiment 2 shown in FIG. 10.

Note that since the shell portions of the quantum dots QDa and the matrix MR are made of ZnS in the present embodiment, FIG. 11 does not show the energy level of the conduction band minimum of the shell portions of the quantum dots QDa, which is equal to the energy level of the conduction band minimum (MR(CBM)) of the matrix MR, and the energy level of the valence band maximum of the shell portions of the quantum dots QDa, which is equal to the energy level of the valence band maximum (MR(VBM)) of the matrix MR.

Referring to FIG. 11, since the hole transport layer 13, which is a carrier transport layer, includes a layer of a mixture of at least the first material 13a and the second material 13b, and the first material 13a differs from the second material 13b, the ionization potential of the first material 13a (the absolute value of the difference between the vacuum energy level and the energy level of the valence band maximum (13a (VBM)) of the first material 13a) differs from the ionization potential of the second material 13b (the absolute value of the difference between the vacuum energy level and the energy level of the valence band maximum (13b (VBM)) of the second material 13b).

As described in the foregoing, the use of the hole transport layer 13 including a layer of a mixture of the first material 13a and the second material 13b, which are different materials, enables appropriately adjusting the energy levels through the injection of holes h from the anode 2 to a light-emitting layer 4a including the matrix MR in comparison with when a hole transport layer composed of a single material is used, thereby enabling readily injecting holes h from the anode 2 to the hole transport layer 13 and also from the hole transport layer 13 to the light-emitting layer 4a including the matrix MR, which in turn enables voltage reduction.

In other words, the use of the hole transport layer 13 including a layer of a mixture of the first material 13a and the second material 13b, which are different materials, enables rendering the ionization potential of the first material 13a and the ionization potential of the second material 5b differ from each other, thereby enabling easily injecting holes h to the light-emitting layer 4a in which the quantum dots QDa and the matrix MR have different energy levels.

In addition, the use of the hole transport layer 13 including a layer of a mixture of the first material 13a and the second material 13b, which are different materials, enables a plurality of energy levels (ionization potentials) at which holes h are injected from the hole transport layer 13 to the light-emitting layer 4a. It also becomes possible to readily move holes h in the hole transport layer 13 from the first material 13a, which exhibits a shallow energy level, to the second material 13b, which exhibits a deep energy level. Consequently, it becomes possible to efficiently inject holes h from the first material 13a and the second material 13b to the quantum dots QDa and the matrix MR, which have different energy levels.

Note that FIG. 11 depicts the energy level of the valence band maximum (QDa(VBM)) of the core portions of the quantum dots QDa as being deeper than the energy level of the valence band maximum (13a (VBM)) of the first material 13a. However, effects that are similar to the effects described above can be achieved when the energy level of the valence band maximum (QDa(VBM)) of the core portions of the quantum dots QDa is shallower than the energy level of the valence band maximum (13a (VBM)) of the first material 13a.

The light-emitting layer 4a has a surface formed of two different materials, that is, the quantum dots QDa and the matrix MR. The hole transport layer 13 likewise including two different materials, that is, a layer of a mixture of the first material 13a and the second material 13b, improves adherence between the light-emitting layer 4a and the hole transport layer 13, thereby enabling improving, for example, conductance and mechanical stress resistance at the interface. In addition, it becomes easier to planarize both the light-emitting layer 4a and the hole transport layer 13, thereby enabling improving the in-plane uniformity of light emission.

Referring to FIG. 11, the ionization potential of the second material 13b (the absolute value of the difference between the vacuum energy level and the energy level of the valence band maximum (13b (VBM)) of the second material 13b) is preferably larger than the ionization potential of the first material 13a (the absolute value of the difference between the vacuum energy level and the energy level of the valence band maximum (13a (VBM)) of the first material 13a), and the ionization potential of the core portions of the quantum dots QDa (the absolute value of the difference between the vacuum energy level and the energy level of the valence band maximum (QDa(VBM)) of the core portions of the quantum dots QDa) is preferably higher than or equal to the ionization potential of the first material 13a.

In this configuration, since the ionization potential increases in the order of the anode 2, the first material 13a, and the core portions of the quantum dots QDa, it becomes possible to inject holes h to the core portions of the quantum dots QDa at a low voltage, which reduces the drive voltage of the light-emitting element 10a.

The ionization potential of the matrix MR (the absolute value of the difference between the vacuum energy level and the energy level of the valence band maximum (MR(VBM)) of the matrix MR) is preferably higher than or equal to the ionization potential of the second material 13b.

In this configuration, since the ionization potential increases in the order of the anode 2, the first material 13a, the second material 13b, and the matrix MR, it becomes possible to inject holes h also to the matrix MR at a low voltage. The holes h injected to the matrix MR can move to the quantum dots QDa, which are positioned away from the hole transport layer 13, and recombine in the quantum dots QDa to emit light. Therefore, it is possible to cause those quantum dots QDa which are located away from the hole transport layer 13 to emit light at a relatively low voltage, which enables achieving a high luminance. A higher voltage allows those quantum dots QDa which are located farther away from the hole transport layer 13 to emit light, thereby enabling reducing roll off. In other words, the current dependency and voltage dependency of the luminous efficiency can be improved, and decreases in the luminous efficiency can be reduced, in particular, in a large current region.

The ionization potential of the second material 13b is preferably higher than the ionization potential of the core portions of the quantum dots QDa.

In this configuration, holes h are readily injected from the first material 13a to the core portions of the quantum dots QDa and also from the second material 13b to the matrix MR, both at a low voltage.

Meanwhile, if the ionization potential of the second material 13b is lower than the ionization potential of the core portions of the quantum dots QDa, holes h are injected from the second material 13b both to the matrix MR and to the core portions of the quantum dots QDa.

The ionization potential of the first material 13a and the ionization potential of the second material 13b preferably differ by at least 0.1 eV.

The difference in the ease of injecting holes changes by approximately 50 times for every 0.1 eV difference in ionization potential, and holes h can be therefore injected to a material with a more suitable ionization potential in preference to other materials.

Each of the first material 13a and the second material 13b is preferably composed of an inorganic compound.

In this configuration, the light-emitting element 10a can exhibit increased reliability.

The first material 13a and the second material 13b are preferably nanoparticles and have volume ratios to the hole transport layer 13 that increase with an increase in their ionization potentials. In the present embodiment, the volume ratio of the second material 13b contained in the hole transport layer 13 is preferably larger than the volume ratio of the first material 13a contained in the hole transport layer 13. This configuration facilitates the injection of holes h to nanoparticles with a high ionization potential, thereby enabling improving the inject of holes h to the matrix MR, which has a low injection efficiency.

The first material 13a and the second material 13b are preferably nanoparticles and have volume ratios to the hole transport layer 13 that increase with a decrease in their ionization potentials in the vicinity of their interface with the anode 2. In the present embodiment, the volume ratio of the first material 13a contained in the hole transport layer 13 is preferably larger than the volume ratio of the second material 13b contained in the hole transport layer 13. This configuration facilitates the injection of holes h from the anode 2 to the hole transport layer 13.

The first material 13a and the second material 13b are preferably nanoparticles and have volume ratios to the hole transport layer 13 that increase with an increase in their ionization potentials in the vicinity of their interface with the light-emitting layer 4a. In the present embodiment, the volume ratio of the second material 13b contained in the hole transport layer 13 is preferably larger than the volume ratio of the first material 13a contained in the hole transport layer 13. This configuration facilitates the injection of holes h from the hole transport layer 13 to the matrix MR.

The first material 13a and the second material 13b are preferably nanoparticles, and the first material 13a preferably decreases from the anode 2 side toward the light-emitting layer 4a side. This configuration presents no obstacle in injecting holes h first to the first material 13a and then to the second material 13b in accordance with the direction in which holes h are flowing, thereby reducing voltage inside the hole transport layer 13 to a minimum. The second material 13b preferably increases from the anode 2 side toward the light-emitting layer 4a side. This configuration presents no obstacle in injecting holes h first to the first material 13a and then to the second material 13b in accordance with the direction in which holes h are flowing, thereby reducing voltage inside the hole transport layer 13 to a minimum.

In the present embodiment, since CdSe (Red) is used as the core portions of the quantum dots QDa, and ZnS is used as the matrix MR, the energy level of the valence band maximum (QDa(VBM)) of the core portions of the quantum dots QDa and the ionization potential of the core portions of the quantum dots QDa are 5.6 eV, and the energy level of the valence band maximum (MR(VBM)) of the matrix MR and the ionization potential of the matrix MR are 7.2 eV. Therefore, the ionization potential of the first material 13a is preferably lower than or equal to 5.6 eV, and the ionization potential of the second material 13b is preferably from 5.6 eV, exclusive, to 7.2 eV, inclusive.

For instance, the first material 13a may be suitably at least one compound selected from AlSb, Cu₂O, and NiO, and the second material 13b may be suitably at least one compound selected from GaP, GaN, ZnS, ZnTe, and LaNiO₃.

It is assumed in this context that the electron affinity and ionization potential of each material have the values shown earlier in Table 1.

The first material 13a and the second material 13b may contain the same elements with the same composition ratio and have different particle diameter distributions.

For instance, in NiO or Cu₂O nanoparticles, the bandgap increases, and the ionization potential increases, with a decrease in the particle diameter due to quantum effects. Therefore, the hole transport layer 13 with two ionization potentials can be provided by changing the particle diameters of the first material 13a and the second material 13b.

The first material 13a and the second material 13b contained in the hole transport layer 13 may contain the same component elements with different composition ratios.

For instance, the first material 13a may be Ni₁₋ₓMgₓO (0≤x<1) nanoparticles with an average particle diameter of 12 nm and an ionization potential of 5.6 eV where x=0.25, and the second material 13b may be Ni₁₋ₓMgₓO (0≤x<1) nanoparticles with an average particle diameter of 12 nm and an ionization potential of 5.8 eV where x=0.5.

Furthermore, the hole transport layer 13 may contain another material(s) such as Cu₂O, NiO, and/or NiO₁₋ₓ(LaNiO₃)ₓ so that the hole transport layer 13 can exhibit another ionization potential(s). These materials (nanoparticles) are prepared by publicly known technology, a mix solution in which the nanoparticles are mixed with an organic solvent such as ethanol is used, and, for example, spin-coating or inkjet printing is employed, to form the hole transport layer 13.

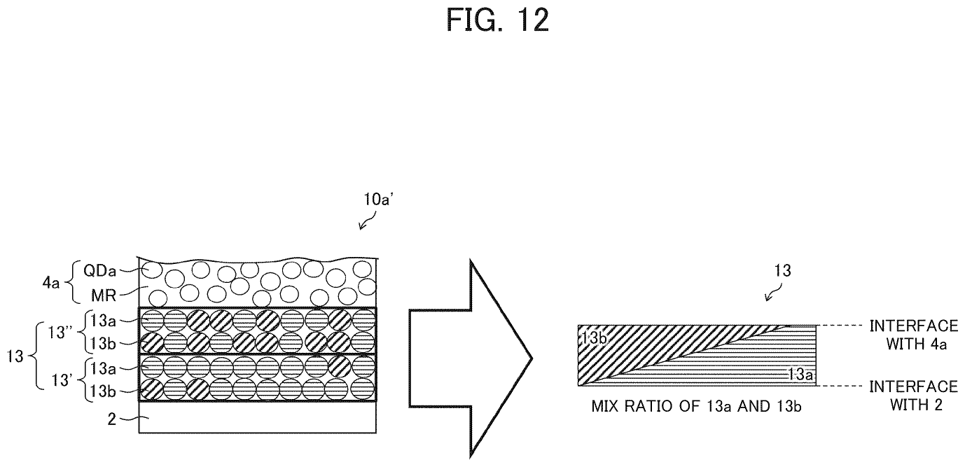

FIG. 12 is a diagram schematically illustrating a structure of a light-emitting element 10a′ in accordance with a variation example of Embodiment 2 and representing a preferable mix ratio of the first material 13a and the second material 13b in the hole transport layer 13.

Referring to FIG. 12, the hole transport layer 13 included in the light-emitting element 10a′ preferably includes a first hole transport layer 13′ and a second hole transport layer 13″, the second hole transport layer 13″ is preferably disposed closer to the light-emitting layer 4a than is the first hole transport layer 13′, the second hole transport layer 13″ preferably contains a mixture of at least the first material 13a and the second material 13b, and the quantity of the first material 13a contained in a unit volume of the first hole transport layer 13′ is preferably greater than the quantity of the first material 13a contained in a unit volume of the second hole transport layer 13″.

At the interface between the anode 2 and the hole transport layer 13 of the light-emitting element 10a′, the first material 13a is preferably present in greater quantity than the second material 13b and more preferably exclusively present with no second material 13b at all. Therefore, for example, the second hole transport layer 13″ may contain a mixture of at least the first material 13a and the second material 13b, and the first hole transport layer 13′ may be composed solely of the first material 13a. This configuration presents no obstacle in injecting holes h first to the first hole transport layer 13′ and then to the second hole transport layer 13″ in accordance with the direction in which holes h are flowing, thereby reducing voltage inside the hole transport layer 13 to a minimum.

Meanwhile, at the interface between the light-emitting layer 4a and the hole transport layer 13 of the light-emitting element 10a′, the first material 13a is preferably present in greater quantity than the second material 13b. This configuration positions the second material 13b, from which it is easy to inject holes h to the matrix MR, in great quantity close to the matrix MR, to which it is difficult to inject holes h, thereby enabling improving luminous efficiency.

In addition, as described above, when the hole transport layer 13 includes a layer of a mixture of the first material 13a and the second material 13b, the hole transport layer 13 may be configured such that the second material 13b gradually increases, and the first material 13a gradually decreases, upon moving from the anode 2 toward the light-emitting layer 4a. This configuration presents no obstacle in injecting holes h first to the first material 13a and then to the second material 13b in accordance with the direction in which holes h are flowing, thereby reducing voltage inside the hole transport layer 13 to a minimum.

The hole transport layer 13 shown in FIG. 12 may be formed by, for example, applying a solution of nanoparticles for the first material 13a by spin-coating and then applying, before drying, a solution of nanoparticles for the second material 13b by spin-coating and may alternatively be formed by, for example, preparing a plurality of solutions of nanoparticles for the first material 13a and nanoparticles for the second material 13b with different mix ratios (mix concentrations) and applying the solutions, one at a time, in descending order of the mix ratio (mix concentration) of the first material 13a in the solution as if forming a stack of layers so that the resultant hole transport layer 13 can exhibit a concentration distribution in the film thickness direction.

Note that the present embodiment has so far discussed an example where the hole transport layer 13 shown in FIG. 12 is formed before the light-emitting layer 4a is formed, which is merely illustrative. Alternatively, for example, when the light-emitting layer 4a, the hole transport layer 13 shown in FIG. 12, and the anode 2 are formed in this order, the hole transport layer 13 may be formed by applying a solution of nanoparticles for the second material 13b by spin-coating and then applying, before drying, a solution of nanoparticles for the first material 13a by spin-coating and may alternatively be formed by preparing a plurality of solutions of nanoparticles for the first material 13a and nanoparticles for the second material 13b with different mix ratios (mix concentrations) and applying the solutions, one at a time, in ascending order of the mix ratio (mix concentration) of the first material 13a in the solution as if forming a stack of layers so that the resultant hole transport layer 13 can exhibit a concentration distribution in the film thickness direction.

### Embodiment 3

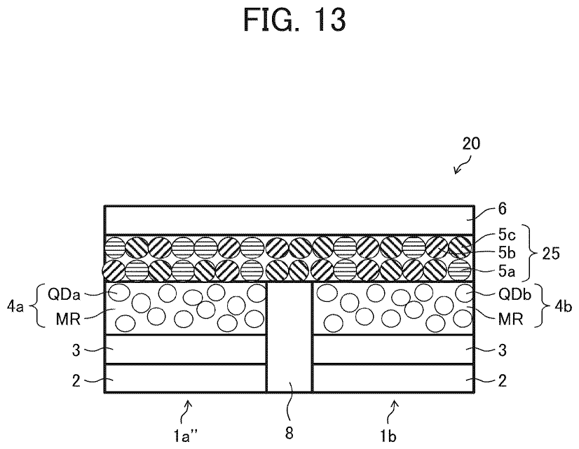

FIG. 13 is a schematic cross-sectional view of a structure of a display device 20 in accordance with Embodiment 3.

Referring to FIG. 13, the display device 20 includes: a light-emitting element (first light-emitting element) 1a″; and a light-emitting element (second light-emitting element) 1b that emits light of a different wavelength than does the light-emitting element 1a″. As an example, the light-emitting element 1a″ may be a red-light-emitting element including a red-light-emitting layer, and the light-emitting element 1b may be a green-light-emitting element including a green-light-emitting layer. The light-emitting element 1a″ contains quantum dots (first quantum dots) QDa, and the light-emitting element 1b contains quantum dots (second quantum dots) QDb. Then, each of the light-emitting element 1a″ and the light-emitting element 1b includes, as a carrier transport layer, an electron transport layer (common electron transport layer) 25 between the cathode 6 and the light-emitting layers 4a and 4b.

The electron transport layer (common electron transport layer) 25 includes a layer of a mixture of a first material 5a, a second material 5b, and a third material 5c that differs from the first material 5a and the second material 5b. The present embodiment discusses an example where the electron transport layer 25 is composed of a layer of a mixture of the first material 5a, the second material 5b, and the third material 5c, which is merely illustrative. Alternatively, the electron transport layer 25 needs only to include a layer of a mixture of the first material 5a, the second material 5b, and the third material 5c.

Note that the portions of the light-emitting element 1a″ and the light-emitting element 1b other than the electron transport layer (common electron transport layer) 25 and the cathode 6, both of which are common layers to the light-emitting element 1a″ and the light-emitting element 1b, are separated by a partition wall 8.

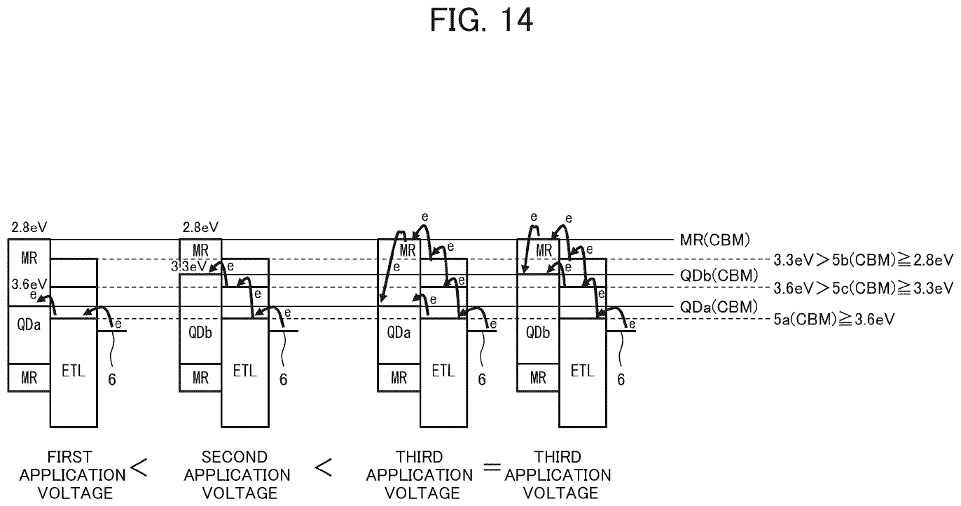

FIG. 14 is an illustration of an injection mechanism for electrons e in the light-emitting elements 1a″ and 1b in the display device 20 in accordance with Embodiment 3 shown in FIG. 13.

In the present embodiment, since CdSe (Red) is used as the core portions of the quantum dots QDa, CdSe (Green) is used as the core portions of the quantum dots QDb, and ZnMgS is used as the matrix MR, the energy level of its conduction band minimum (QDa(CBM)) of the core portions of the quantum dots QDa is 3.6 eV, the energy level of the conduction band minimum (QDb(CBM)) of the core portions of the quantum dots QDb is 3.3 eV, and the energy level of the conduction band minimum (MR(CBM)) of the matrix MR is 2.8 eV, as shown in FIG. 14.

When the energy level of the conduction band minimum (QDa(CBM)) of the core portions of the quantum dots QDa, the energy level of the conduction band minimum (QDb(CBM)) of the core portions of the quantum dots QDb, and the energy level of the conduction band minimum (MR(CBM)) of the matrix MR are as shown in FIG. 14, the energy level of the conduction band minimum (5a(CBM)) of the first material 5a needs only to be at least 3.6 eV, the energy level of the conduction band minimum (5b(CBM)) of the second material 5b needs only to be from 2.8 eV, inclusive, to 3.3 eV, exclusive, and the energy level of the conduction band minimum (5c (CBM)) of the third material 5c needs only to be from 3.3 eV, inclusive, to 3.6 eV, exclusive. In other words, the electron affinity of the first material 5a needs only to be at least 3.6 eV, the electron affinity of the second material 5b needs only to be from 2.8 eV, inclusive, to 3.3 eV, exclusive, and the electron affinity of the third material 5c needs only to be from 3.3 eV, inclusive, to 3.6 eV, exclusive.

Therefore, in the display device 20 in accordance with the present embodiment, the magnitudes of the electron affinities of the matrix MR, the core portions of the quantum dots (first quantum dots) QDa, the core portions of the quantum dots (second quantum dots) QDb, the first material 5a, the second material 5b, and the third material 5c have a relationship: Matrix MR (2.8 eV)≤Second Material 5b (from 2.8 eV, inclusive, to 3.3 eV, exclusive)<Core Portions of Quantum Dots (Second Quantum Dots) QDb (3.3 eV)≤Third Material 5c (from 3.3 eV, inclusive, to 3.6 eV, exclusive)<Core Portions of Quantum Dots (First Quantum Dots) QDa (3.6 eV)≤First Material 5a (at least 3.6 eV).

The first material 5a may be suitably at least one compound selected from TiO₂ and SnO₂, the second material 5b may be suitably at least one compound selected from GaN, ZnS, ZnTe, Ca₂SnO₄, and CaSnO₃, and the third material 5c may be suitably at least one compound selected from GaP, AlSb, ZrO₂, and CuO₂.

In addition, when the first material 5a, the second material 5b, and the third material 5c are ZnO nanoparticles, the first material 5a may be ZnO nanoparticles with an average particle diameter of at least 4.5 nm and a radius of at least 2.25 nm, the second material 5b may be ZnO nanoparticles with an average particle diameter of from 2.5 nm, inclusive, to 3.5 nm, exclusive, and a radius of from 1.25 nm, inclusive, to 1.75 nm, exclusive, and the third material 5c may be ZnO nanoparticles with an average particle diameter of from 3.5 nm, inclusive, to 4.5 nm, exclusive, and a radius of from 1.75 nm, inclusive, to 2.25 nm, exclusive.

The first material 5a, the second material 5b, and the third material 5c may contain the same elements with the same composition ratio and have mutually different particle diameter distributions.

Meanwhile, when the first material 5a, the second material 5b, and the third material 5c are Zn₁₋ₓMgₓO nanoparticles with an average particle diameter of 12 nm, as an example, the first material 5a may be such nanoparticles that satisfy x≤0.15, the second material 5b may be such nanoparticles that satisfy 0.3<x≤0.55, and the third material 5c may be such nanoparticles that satisfy 0.15<x≤0.3.

The present embodiment has so far discussed an example where the matrix MR in the light-emitting element 1a″ and the matrix MR in the light-emitting element 1b are composed of the same material, which is merely illustrative. Alternatively, the matrix MR in the light-emitting element 1a″ and the matrix MR in the light-emitting element 1b may be composed of different materials. In addition, the electron transport layer (common electron transport layer) 25, which is a common layer to the light-emitting element 1a″ and the light-emitting element 1b, may be separated by the partition wall 8 so long as the electron transport layer (common electron transport layer) 25 contains the same material.

In the display device 20, electrons e are injected in descending order of the electron affinity in response to voltage application as shown in FIG. 14. In other words, electrons e are injected from the first material 5a to the core portions of the quantum dots (first quantum dots) QDa at the first application voltage, which is the lowest application voltage, electrons e are injected from the third material 5c to the core portions of the quantum dots (second quantum dots) QDb at the second application voltage at which the application voltage is higher than the first application voltage, and electrons e are injected from the second material 5b via the matrix MR to the core portions of the quantum dots (first quantum dots) QDa and the core portions of the quantum dots (second quantum dots) QDb, which are located away from the electron transport layer (common electron transport layer) 25, at the third application voltage at which the application voltage is higher than the second application voltage, thereby emitting light.

The display device 20 can reduce the number of steps in the manufacture of the display device 20 because the light-emitting element 1a″ and the light-emitting element 1b, which emit light of different wavelengths, can efficiently emit light at a low voltage and also because the electron transport layer 25 is a common electron transport layer to the light-emitting element 1a″ and the light-emitting element 1b.

### Embodiment 4

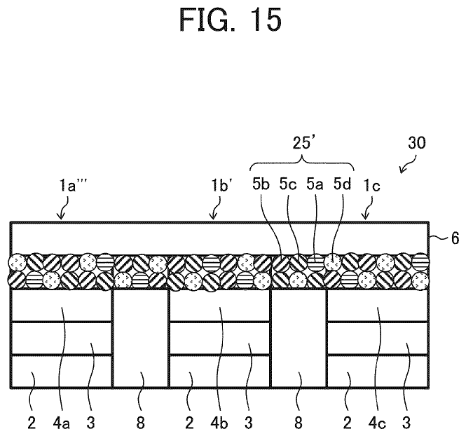

FIG. 15 is a schematic cross-sectional view of a structure of a display device 30 in accordance with Embodiment 4.

The display device 30 shown in FIG. 15 includes: a first light-emitting element 1a′″; a second light-emitting element 1b′; and a third light-emitting element 1c that emits light of a different wavelength than do the first light-emitting element 1a′″ and the second light-emitting element 1b′. In addition, an electron transport layer (common electron transport layer) 25′ includes a layer of a mixture of a first material 5a, a second material 5b, a third material 5c, and a fourth material 5d that differs from the first material 5a, the second material 5b, and the third material 5c. The first light-emitting element 1a′″, the second light-emitting element 1b′, and the third light-emitting element 1c include the electron transport layer (common electron transport layer) 25′ that is common to the first light-emitting element 1a′″, the second light-emitting element 1b′, and the third light-emitting element 1c. As an example, the light-emitting element 1a′″ may be a red-light-emitting element including a red-light-emitting layer, the light-emitting element 1b′ may be a green-light-emitting element including a green-light-emitting layer, and the third light-emitting element 1c may be a blue-light-emitting element including a blue-light-emitting layer.

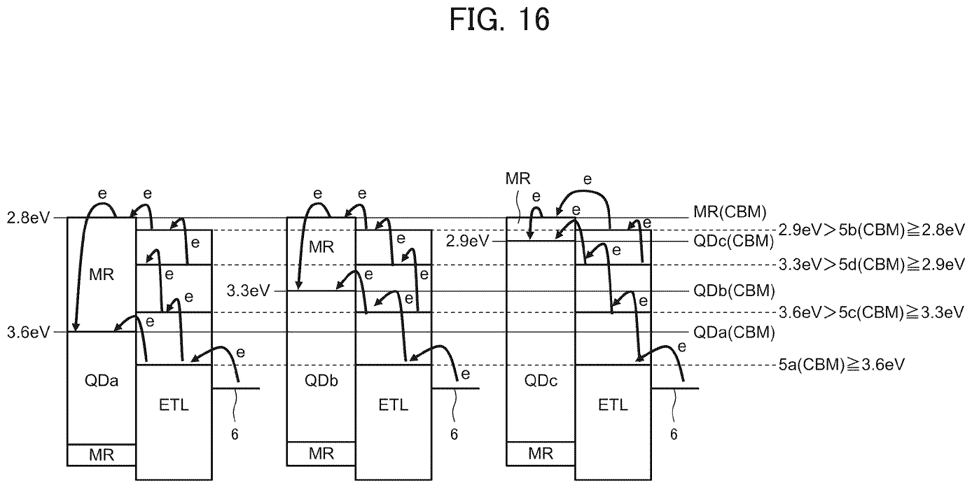

FIG. 16 is an illustration of an electron injection mechanism in the light-emitting element 1a′″, the light-emitting element 1b′, and the light-emitting element 1c in the display device 30 in in accordance with Embodiment 4 shown in FIG. 15.

In the present embodiment, since CdSe (Red) is used as the core portions of quantum dots QDa, CdSe (Green) is used as the core portions of quantum dots QDb, CdSe (Blue) is used as the core portions of quantum dots QDc, and ZnMgS is used as the matrix MR, the energy level of the conduction band minimum (QDa(CBM)) of the core portions of the quantum dots QDa is 3.6 eV, the energy level of the conduction band minimum (QDb(CBM)) of the core portions of the quantum dots QDb is 3.3 eV, the energy level of the conduction band minimum (QDc(CBM)) of the core portions of the quantum dots QDc is 2.9 eV, and the energy level of the conduction band minimum (MR(CBM)) of the matrix MR is 2.8 eV, as shown in FIG. 16.

When the energy level of the conduction band minimum (QDa(CBM)) of the core portions of the quantum dots QDa, the energy level of the conduction band minimum (QDb(CBM)) of the core portions of the quantum dots QDb, the energy level of the conduction band minimum (QDc(CBM)) of the core portions of the quantum dots QDc, and the energy level of the conduction band minimum (MR(CBM)) of the matrix MR are as shown in FIG. 16, the energy level of the conduction band minimum (5a(CBM)) of the first material 5a needs only to be at least 3.6 eV, the energy level of the conduction band minimum (5b(CBM)) of the second material 5b needs only to be from 2.8 eV, inclusive, to 2.9 eV, exclusive, the energy level of the conduction band minimum (5c (CBM)) of the third material 5c needs only to be from 3.3 eV, inclusive, to 3.6 eV, exclusive, and the energy level of the conduction band minimum (5d (CBM)) of the fourth material 5d needs only to be from 2.9 eV, inclusive, to 3.3 eV, exclusive. In other words, the electron affinity of the first material 5a needs only to be at least 3.6 eV, the electron affinity of the second material 5b needs only to be from 2.8 eV, inclusive, to 2.9 eV, exclusive, the electron affinity of the third material 5c needs only to be from 3.3 eV, inclusive, to 3.6 eV, exclusive, and the electron affinity of the fourth material 5d needs only to be from 2.9 eV, inclusive, to 3.3 eV, exclusive.

Therefore, in the display device 30 in accordance with the present embodiment, the magnitudes of the electron affinities of the matrix MR, the core portions of the first quantum dots QDa, the core portions of the second quantum dots QDb, the core portions of the third quantum dots QDc, the first material 5a, the second material 5b, the third material 5c, and the fourth material 5d have a relationship: Matrix MR (2.8 eV)≤Second Material 5b (from 2.8 eV, inclusive, to 2.9 eV, exclusive)<Core Portions of Third Quantum Dots QDc (2.9 eV)≤Fourth Material 5d (2.9 eV, inclusive, to 3.3 eV, exclusive)<Core Portions of Second Quantum Dots QDb (3.3 eV)≤Third Material 5c (from 3.3 eV, inclusive, to 3.6 eV, exclusive)<Core Portions of First Quantum Dots QDa (3.6 eV)≤First Material 5a (at least 3.6 eV).

The present embodiment has so far also discussed an example where the matrix MR in the light-emitting element 1a″, the matrix MR in the light-emitting element 1b′, and the matrix MR in the light-emitting element 1c are composed of the same material, which is merely illustrative. Alternatively, the matrix MR in the light-emitting element 1a′″, the matrix MR in the light-emitting element 1b′, and the matrix MR in the light-emitting element 1c may be composed of different materials. In addition, the electron transport layer (common electron transport layer) 25′, which is a common layer to the light-emitting element 1a″, the light-emitting element 1b′, and the light-emitting element 1c, may be separated by a partition wall 8 so long as the electron transport layer (common electron transport layer) 25′ contains the same material.

The display device 30 can reduce the number of steps in the manufacture of the display device 30 because the light-emitting element 1a′″, the light-emitting element 1b′, and the light-emitting element 1c, which emit light of different wavelengths, can efficiently emit light at a low voltage and also because the electron transport layer 25 is a common electron transport layer to the light-emitting element 1a′″, the light-emitting element 1b′, and the light-emitting element 1c.

### Embodiment 5

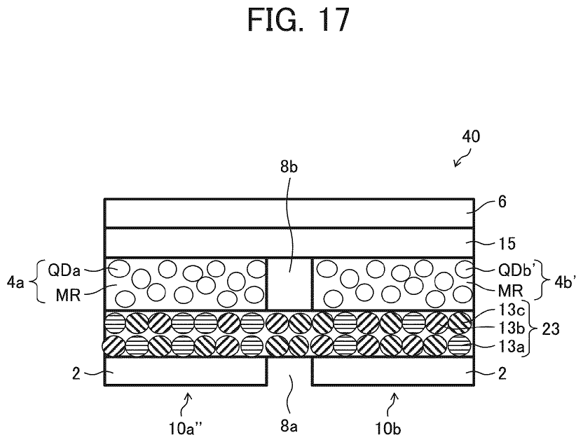

FIG. 17 is a schematic cross-sectional view of a structure of a display device 40 in accordance with Embodiment 5.

Referring to FIG. 17, the display device 40 includes: a light-emitting element (first light-emitting element) 10a″; and a light-emitting element (second light-emitting element) 10b that emits light of a different wavelength than does the light-emitting element 10a″. As an example, the light-emitting element 10a″ may be a red-light-emitting element including a red-light-emitting layer, and the light-emitting element 10b may be a green-light-emitting element including a green-light-emitting layer. The light-emitting element 10a″ contains quantum dots (first quantum dots) QDa, and the light-emitting element 10b contains quantum dots (second quantum dots) QDb′. Then, each of the light-emitting element 10a″ and the light-emitting element 10b includes, as a carrier transport layer, a hole transport layer (common hole transport layer) 23 between the anode 2 and the light-emitting layers 4a and 4b.

The hole transport layer (common hole transport layer) 23 includes a layer of a mixture of a first material 13a, a second material 13b, and a third material 13c that differs from the first material 13a and the second material 13b. The present embodiment discusses an example where the hole transport layer 23 is composed of a layer of a mixture of the first material 13a, the second material 13b, and the third material 13c, which is merely illustrative. Alternatively, the hole transport layer 23 needs only to include a layer of a mixture of the first material 13a, the second material 13b, and the third material 13c.

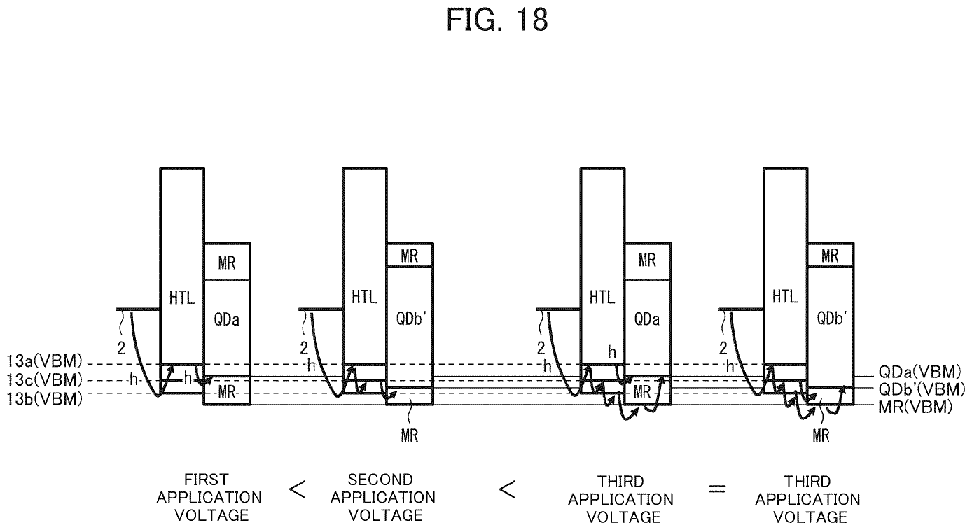

Note that the portions of the light-emitting element 10a″ and the light-emitting element 10b other than the hole transport layer (common hole transport layer) 23, the electron transport layer 15, and the cathode 6, all of which are common layers to the portions of the light-emitting element 10a″ and the light-emitting element 10b, are separated by partition walls 8a and 8b. FIG. 18 is an illustration of a hole injection mechanism in the light-emitting element 10a″ and the light-emitting element 10b in the display device 40 in accordance with Embodiment 5 shown in FIG. 17.

In the present embodiment, since CdSe (Red) is used as the core portions of the quantum dots QDa, ZnSe (Blue) is used as the core portions of the quantum dots QDb′, and ZnS is used as the matrix MR, the energy level of the valence band maximum (QDa(VBM)) of the core portions of the quantum dots QDa and the ionization potential of the core portions of the quantum dots QDa are 5.6 eV, the energy level of the valence band maximum (QDb′ (VBM)) of the core portions of the quantum dots QDb′ and the ionization potential of the core portions of the quantum dots QDb′ are 5.8 eV, and the energy level of the valence band maximum (MR(VBM)) of the matrix MR and the ionization potential of the matrix MR are 7.2 eV. Therefore, the ionization potential of the first material 13a is preferably lower than or equal to 5.6 eV, the ionization potential of the second material 13b is preferably from 5.8 eV, exclusive, to 7.2 eV, inclusive, and the ionization potential of the third material 13c is preferably from 5.6 eV, exclusive, to 5.8 eV, inclusive.

Thus, in the display device 40 in accordance with the present embodiment, the magnitudes of the ionization potentials of the matrix MR, the core portions of the first quantum dots QDa, the core portions of the second quantum dots QDb′, the first material 13a, the second material 13b, and the third material 13c have a relationship: Matrix MR (7.2 eV)≥Second Material 13b (from 5.8 eV, exclusive, to 7.2 eV, inclusive)>Core Portions of Second Quantum Dots QDb′ (5.8 eV)≥Third Material 13c (from 5.6 eV, exclusive, to 5.8 eV, inclusive)>Core Portions of First Quantum Dots QDa (5.6 eV)≥First Material 13a (less than or equal to 5.6 eV).

Note that, for example, ZnTe may be used as the third material 13c.

The present embodiment has so far discussed an example where the matrix MR in the light-emitting element 10a″ and the matrix MR in the light-emitting element 10b are composed of the same material, which is merely illustrative. Alternatively, the matrix MR in the light-emitting element 10a″ and the matrix MR in the light-emitting element 10b may be composed of different materials. In the light-emitting element 10a″ and the light-emitting element 10b, the hole transport layer (common hole transport layer) 23, which is a common layer, may be separated by the partition walls 8a and 8b so long as the hole transport layer (common hole transport layer) 23 contains the same material.

In the display device 40, holes h are injected from the first material 13a to the core portions of the quantum dots (first quantum dots) QDa at the first application voltage, which is the lowest application voltage, holes h are injected from the third material 13c to the core portions of the quantum dots (second quantum dots) QDb′ at the second application voltage at which the application voltage is higher than the first application voltage, and holes h are injected from the second material 13b via the matrix MR to the core portions of the quantum dots (first quantum dots) QDa and the core portions of the quantum dots (second quantum dots) QDb′, which are located away from the hole transport layer (common hole transport layer) 23, at the third application voltage at which the application voltage is higher than the second application voltage, thereby emitting light, as shown in FIG. 18.

The display device 40 can reduce the number of steps in the manufacture of the display device 40 because the light-emitting element 10a″ and the light-emitting element 10b, which emit light of different wavelengths, can efficiently emit light at a low voltage and also because the hole transport layer 23 is a common hole transport layer to the light-emitting element 10a″ and the light-emitting element 10b.

The display device 40 may include a light-emitting element (third light-emitting element) (not shown) that emits light of a different wavelength than do the light-emitting element 10a″ and the light-emitting element 10b. The light-emitting element (third light-emitting element) contains third quantum dots as quantum dots. The light-emitting element 10a″, the light-emitting element 10b, and the light-emitting element (third light-emitting element) include, as a carrier transport layer, a common hole transport layer between the anode 2 and the light-emitting layer.

The common hole transport layer includes a layer of a mixture of the first material 13a, the second material 13b, the third material 13c, and a fourth material that differs from the first material 13a, the second material 13b, and the third material 13c. When this is the case, the magnitudes of the ionization potentials of the matrix MR, the core portions of the first quantum dots QDa, the core portions of the second quantum dots QDb′, the core portions of the third quantum dots, the first material 13a, the second material 13b, the third material 13c, and the fourth material have a relationship: Matrix MR≥Second Material 13b>Core Portions of Third Quantum Dots≥Fourth Material>Core Portions of Second Quantum Dots QDb′≥Third Material 13c>Core Portions of First Quantum Dots QDa≥First Material 13a.

### Embodiment 6

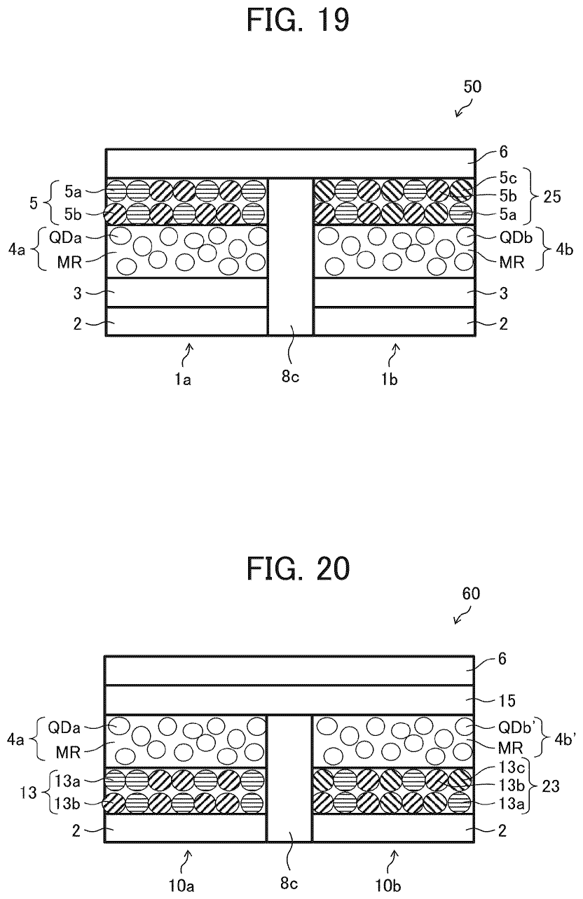

FIG. 19 is a schematic cross-sectional view of a structure of a display device 50 in accordance with Embodiment 6.

Referring to FIG. 19, the display device 50 includes: a light-emitting element (first light-emitting element) 1a; and a light-emitting element 1b (second light-emitting element) that emits light of a different wavelength than does the light-emitting element (first light-emitting element) 1a. The light-emitting element 1a includes: quantum dots (first quantum dots) QDa; and an electron transport layer 5 as a carrier transport layer. The light-emitting element 1b includes: quantum dots (second quantum dots) QDb; and an electron transport layer 25 as a carrier transport layer. The electron transport layer 5 includes a layer of a mixture of the first material 5a and the second material 5b. The electron transport layer 25 includes a layer of a mixture of the first material 5a, the second material 5b, and a third material 5c that differs from the first material 5a and the second material 5b.

The display device 50 may include a light-emitting element (third light-emitting element) (not shown) that emits light of a different wavelength than do the light-emitting element (first light-emitting element) 1a and the light-emitting element 1b (second light-emitting element). The light-emitting element (third light-emitting element) includes quantum dots (third quantum dots) and an electron transport layer as a carrier transport layer. The electron transport layer included in the light-emitting element (third light-emitting element) includes a layer of a mixture of the first material 5a, the second material 5b, the third material 5c, and a fourth material that differs from the first material 5a, the second material 5b, and the third material 5c.

Note that in the display device 50, the portions other than the cathode 6, which is a common layer, are separated by a partition wall 8c.

In the display device 50, the use of a plurality of electron transport layers of different materials enables appropriately adjusting the energy levels through the injection of electrons e from the cathode 6 to a light-emitting layer including the matrix MR, thereby enabling readily injecting electrons e from the cathode 6 to the electron transport layers and also from the electron transport layers to the light-emitting layer including the matrix MR, which in turn enables voltage reduction.

### Embodiment 7

FIG. 20 is a schematic cross-sectional view of a structure of a display device 60 in accordance with Embodiment 7.

Referring to FIG. 20, the display device 60 includes: a light-emitting element (first light-emitting element) 10a; and a light-emitting element 10b (second light-emitting element) that emits light of a different wavelength than does the light-emitting element (first light-emitting element) 10a. The light-emitting element 10a includes: quantum dots (first quantum dots) QDa; and a hole transport layer 13 as a carrier transport layer. The light-emitting element 10b includes quantum dots (second quantum dots) QDb′; and a hole transport layer 23 as a carrier transport layer. The hole transport layer 13 includes a layer of a mixture of the first material 13a and the second material 13b. The hole transport layer 23 includes a layer of a mixture of the first material 13a, the second material 13b, and a third material 13c that differs from the first material 13a and the second material 13b.

The display device 60 may include a light-emitting element (third light-emitting element) (not shown) that emits light of a different wavelength than do the light-emitting element (first light-emitting element) 10a and the light-emitting element 10b (second light-emitting element). The light-emitting element (third light-emitting element) includes quantum dots (third quantum dots) and a hole transport layer as a carrier transport layer. The hole transport layer included in the light-emitting element (third light-emitting element) includes a layer of a mixture of the first material 13a, the second material 13b, the third material 13c, and a fourth material that differs from the first material 13a, the second material 13b, and the third material 13c.

Note that in the display device 60, the portions other than the electron transport layer 15 and the cathode 6, which are common layers, are separated by a partition wall 8c.

In the display device 60, the use of a plurality of hole transport layers of different materials enables appropriately adjusting the energy levels through the injection of holes h from the anode 2 to a light-emitting layer including the matrix MR, thereby enabling readily injecting holes h from the anode 2 to the hole transport layers and the injection of holes h from the hole transport layers to the light-emitting layer including the matrix MR, which in turn enables voltage reduction.

### ADDITIONAL REMARKS

The present disclosure is not limited to the description of the embodiments above and may be altered within the scope of the claims. Embodiments based on a proper combination of technical means disclosed in different embodiments are encompassed in the technical scope of the present disclosure. Furthermore, new technical features can be created by combining different technical means disclosed in the embodiments.

### INDUSTRIAL APPLICABILITY

The present disclosure is applicable to light-emitting elements and display devices.

1. A light-emitting element comprising:
an anode;
a cathode;
a light-emitting layer provided between the anode and the cathode; and
a carrier transport layer provided between either the anode or the cathode and the light-emitting layer, wherein
the light-emitting layer includes a plurality of quantum dots and a matrix provided at least partially between the plurality of quantum dots,
the carrier transport layer includes a layer of a mixture of at least a first material and a second material, and
the first material differs from the second material.

2. The light-emitting element according to claim 1, wherein in the light-emitting layer, the matrix is loaded between the plurality of quantum dots.

3. The light-emitting element according to claim 1, wherein the first material and the second material are nanoparticles.

4. The light-emitting element according to claim 1, wherein the first material and the second material contain different component elements.

5. The light-emitting element according to claim 1, wherein
the first material and the second material contain a same component element, and
the first material and the second material have different composition ratios.

6. The light-emitting element according to claim 3, wherein
the first material and the second material contain a same element and have a same composition ratio, and
the first material and the second material have different particle diameter distributions.

7.-12. (canceled)

13. The light-emitting element according to claim 1, wherein
the carrier transport layer is a hole transport layer provided between the anode and the light-emitting layer, and
the first material and the second material have different ionization potentials.

14. The light-emitting element according to claim 13, wherein
the ionization potential of the second material is higher than the ionization potential of the first material, and
the plurality of quantum dots includes core portions that have an ionization potential higher than or equal to the ionization potential of the first material.

15. The light-emitting element according to claim 14, wherein the matrix has an ionization potential higher than or equal to the ionization potential of the second material.

16. The light-emitting element according to claim 14, wherein the ionization potential of the second material is higher than the ionization potential of the core portions of the plurality of quantum dots.

17. The light-emitting element according to claim 13, wherein the ionization potential of the first material and the ionization potential of the second material differ by at least 0.1 eV.

18. The light-emitting element according to claim 14, wherein
the hole transport layer includes a first hole transport layer and a second hole transport layer,
the second hole transport layer is disposed closer to the light-emitting layer than is the first hole transport layer,
the second hole transport layer is a layer of a mixture of at least the first material and the second material, and
the first hole transport layer contains the first material in a greater quantity per unit volume than does the second hole transport layer.

19. The light-emitting element according to claim 1, wherein the first material and the second material contain an inorganic compound.

20. The light-emitting element according to claim 1, wherein the matrix contains a metal sulfide.

21. A display device comprising a plurality of the light-emitting elements according to claim 1, wherein
the plurality of light-emitting elements includes a first light-emitting element and a second light-emitting element that emits light of a different wavelength than does the first light-emitting element,
the first light-emitting element includes first quantum dots as the plurality of quantum dots,
the second light-emitting element includes second quantum dots as the plurality of quantum dots,
each of the first light-emitting element and the second light-emitting element includes, as the carrier transport layer, a common electron transport layer between the cathode and the light-emitting layer,
the common electron transport layer includes a layer of a mixture of at least the first material, the second material, and a third material that differs from the first material and the second material, and
the matrix, core portions of the first quantum dots, core portions of the second quantum dots, the first material, the second material, and the third material have electron affinities with magnitudes that have a relationship: Matrix≤Second Material<Core Portions of Second Quantum Dots≤Third Material<Core Portions of First Quantum Dots≤First Material.

22. The display device according to claim 21, wherein
the plurality of light-emitting elements further includes a third light-emitting element that emits light of a different wavelength than do the first light-emitting element and the second light-emitting element,
the third light-emitting element includes third quantum dots as the plurality of quantum dots, and the common electron transport layer between a light-emitting layer of the third light-emitting element and the cathode,
the common electron transport layer further includes a fourth material that differs from the first material, the second material, and the third material, and
core portions of the third quantum dots and the fourth material have electron affinities with magnitudes that have a relationship: Second Material<Core Portions of Third Quantum Dots≤Fourth Material<Core Portions of Second Quantum Dots.

23. A display device comprising a plurality of the light-emitting elements according to claim 1, wherein
the plurality of light-emitting elements includes a first light-emitting element and a second light-emitting element that emits light of a different wavelength than does the first light-emitting element,
the first light-emitting element includes first quantum dots as the plurality of quantum dots,
the second light-emitting element includes second quantum dots as the plurality of quantum dots,
each of the first light-emitting element and the second light-emitting element includes, as the carrier transport layer, a common hole transport layer between the anode and the light-emitting layer,
the common hole transport layer includes a layer of a mixture of at least the first material, the second material, and a third material that differs from the first material and the second material, and
the matrix, core portions of the first quantum dots, core portions of the second quantum dots, the first material, the second material, and the third material have ionization potentials with magnitudes that have a relationship: Matrix≥Second Material>Core Portions of Second Quantum Dots≥Third Material>Core Portions of First Quantum Dots≥First Material.

24. The display device according to claim 23, wherein
the plurality of light-emitting elements further includes a third light-emitting element that emits light of a different wavelength than do the first light-emitting element and the second light-emitting element,
the third light-emitting element includes third quantum dots as the plurality of quantum dots, and a common hole transport layer between a light-emitting layer of the third light-emitting element and the anode,
the common hole transport layer further includes a fourth material that differs from the first material, the second material, and the third material, and
core portions of the third quantum dots and the fourth material have ionization potentials with magnitudes that have a relationship: Second Material>Core Portions of Third Quantum Dots≥Fourth Material>Core Portions of Second Quantum Dots.

25. A display device comprising a plurality of the light-emitting elements according to claim 1, wherein
the plurality of light-emitting elements includes a first light-emitting element and a second light-emitting element that emits light of a different wavelength than does the first light-emitting element,
the first light-emitting element includes first quantum dots as the plurality of quantum dots and a first carrier transport layer as the carrier transport layer,
the second light-emitting element includes second quantum dots as the plurality of quantum dots and a second carrier transport layer as the carrier transport layer,
the first carrier transport layer includes a layer of a mixture of the first material and the second material, and
the second carrier transport layer includes a layer of a mixture of the first material, the second material, and a third material that differs from the first material and the second material.

26. The display device according to claim 25, wherein
the plurality of light-emitting elements further includes a third light-emitting element that emits light that differs than do the first light-emitting element and the second light-emitting element,
the third light-emitting element includes third quantum dots as the plurality of quantum dots and a third carrier transport layer as the carrier transport layer, and
the third carrier transport layer includes a layer of a mixture of the first material, the second material, the third material, and a fourth material that differs from the first material, the second material, and the third material.
